(19) United States
(12) Patent Application Publication
(10) Pub. No.: US 2007/0134426 A1
(43) Pub. Date: Jun. 14, 2007

(54) Vacuum evaporation deposition method of the winding type and vacuum evaporation deposition apparatus of the same

(76) Inventors: Nobuhiro Hayashi, Kanagawa (JP); Takayoshi Hirono, Kanagawa (JP); Isao Tada, Kanagawa (JP); Atsushi Nakatsuka, Kanagawa (JP)

Correspondence Address: Floyd B Carothers;Carothers & Carothers, Suite 500, 445 Fort Pitt Boulevard, Pittsburgh, PA, 15219, US

(21) Appl. No.: 10/574,715

(22) PCT Filed: Nov. 12, 2004
(86) PCT No.: PCT/JP04/16839

§ 371 Date: Mar. 27, 2006

(30) Foreign Application Priority Data
Nov. 20, 2003 (JP) 2003-390105

(51) Int. Cl. B05D 3/00; C23C 8/00; H05B 6/02; C23C 16/00; B29C 71/04

(52) U.S. Cl. 427/398.1; 427/585; 427/591; 427/592; 427/532; 118/718; 118/726

(57) ABSTRACT

The invention provides a vacuum evaporation deposition method of the winding type and a vacuum evaporation deposition apparatus of the winding type which can form a metal film on a base film made of a single layer of insulating material such as plastic film without thermal deformation, and which is superior in productivity. An electron beam irradiator 21 irradiates an electron beam onto an insulating material base film 12 before deposition of metal, and a DC bias power source 22 applies bias voltage between an auxiliary roller 18 for guiding the base film 12 with metal film deposited thereon and a can roller 14, whereby the base film 12 charged by the irradiation of the electron beam before the deposition of metal film, is made to be in close contact with the can roller 14. The base film 12 after deposition of metal film is made to be in close contact with the can roller 14 by the bias voltage applied between the auxiliary roller 18 connected electrically to the metal film and the can roller 14.

### TECHNICAL FIELD

This invention relates to a vacuum evaporation deposition method of the winding type in which an insulting base film is continuously dispensed in a reduced pressure atmosphere, and cooled by a cooling roller in close contact, and a metal film is deposited on the insulating film and the metal-deposited film is wound up on a take-up roller.

### BACKGROUND OF THE TECHNIQUE

In the prior art, such an evaporation deposition method of the winding type is known in which a long base film of insulating material is continuously dispensed from a dispense roller, passed along in contact with a cooling can roller and evaporation material from an evaporation source facing to the can roller is deposited on the base film, and the deposited base film is wound up on a take-up roller. That method is disclosed, for example, in the following patent literature 1.

In the vacuum evaporation deposition method of this kind, a base film of insulating material is cooled in contact with the peripheral surface of a cooling can roller to prevent thermal deformation, and a film is formed on the cooled base film. Accordingly, it is an important problem as to how the base film is closely contacted with the cooling can roller, in such a vacuum evaporation deposition method.

An arrangement to obtain a close contact between the material film and the cooling can roller is disclosed, for example, in the following patent literature 2. FIG. 5 of the present disclosure shows a schematic construction of a film-forming apparatus of the winding type, described in the patent literature 2, in which the film is deposited by the plasma CVD method.

Referring to FIG. 5, a dispense roller 3 with a wound base film 2 thereon, and on which a metal film is formed, a cooling can roller 4 and a take-up roller 5 are arranged in a vacuum chamber 1 under reduced pressure. A reaction gas supply source 6 is arranged under the cooling can roller 4. A primary conductive thin film is formed on an insulating film 2, in the form of a metal film. A reaction gas from a reaction gas supply source 6 reacts on the primary conductive thin film to form the film. An insulating layer is formed on the surface of the can roller 4 which is made of metal. A predetermined negative potential is applied onto the roll body.

An electron beam radiator 7 is arranged between the dispensing roller 3 and the can roller 4, in the film-forming apparatus (plasma CVD) of the winding type as shown in FIG. 5. A guide roller 8 is arranged between the electron beam radiator 7 and the can roller 4 to contact the conductive film of the film 2 to ground. Thus, the film 2 with metal film applied is charged with the electron beam from radiator 7 onto the insulating layer surface thereof. The film 2 is closely contacted with the can roller 4, by the electrical attractive force between the can roller 4 and the film 2 with metal film.

Patent Document 1: JP7-118835A

Patent Document 2: JP2000-17440A

### DISCLOSURE OF INVENTION

[Problem to Be Solved by the Invention

However, only plastic film with conductive film already applied, such as the film 2 with metal film applied, is applicable for use in the prior art film-forming apparatus (plasma CVD) as shown in FIG. 5. There is a problem that the prior art apparatus is not suitable for metal film deposition on a base film such as plastics.

In the prior art film-forming apparatus (CVD) of the winding type, bias potential applied to the cooling can roller can be effective on the film with metal film which is already formed thereon. However, when a metal film is newly deposited, the bias potential cannot be applied to the base film before the metal film deposition. When only a material film is charged before the metal film is deposited, electric charges are diffused onto the deposited metal film during the metal deposition. In that case, the electro-static attractive force is lowered between the can roller and the material film and so the contact force is deteriorated.

Accordingly, the charge method and the bias application method employed in the prior art deposition apparatus of the winding type are not suitable for metal film deposition on the base film such as plastic film, and a high contact force cannot be obtained between the cooling can roller and the metal film. The base film is shrunk and deformed due to the deficiency of the cooling effect of the base film. The running speed of the base film cannot be raised. Accordingly, the productivity cannot be improved.

This present invention has been made in consideration of the above problems. It is an object of this invention to provide a vacuum evaporation deposition method of the winding type and a vacuum evaporation deposition apparatus of the winding type in which a thermal deformation of a base film such as plastic is suppressed and a metal film can be formed at a high speed, with superior inproductivity.

[Means for Solving Problem]

The above-described object can be achieved in accordance with the teachings of the present invention by a vacuum evaporation deposition method of the winding type in which a insulating material base film is continuously dispensed in reduced pressure, the film is cooled by a cooling roller in contact therewith, and a metal film is deposited on the base film. The film is made to be in close contact with the cooling roller by electrifying the base film before the metal film deposition and the film is made to be in close contact with the cooling roller by applying a voltage between the metal film and the cooling roller after the deposition of the metal film.

Further, the object of this invention is achieved by a vacuum evaporation deposition apparatus of the winding type which includes a vacuum chamber, unwinding means for continuously dispensing a base film, arranged in the vacuum chamber, take-up means receiving the base film dispensed from the unwinding means, a cooling roller for cooling the film in close contact, arranged between the unwinding means and the take-up means, and an evaporation source is arranged facing to the cooling roller for depositing metal film on the base film. The invention is characterized in that the apparatus includes charged-particle irradiating means for irradiating charged-particles onto the base film, arranged between the unwinding means and the evaporation source, an auxiliary roller arranged between the cooling roller and the take-up means, for guiding the running of the base film in contact with the deposited surface of the base film, and voltage applying means for applying a DC voltage between the cooling roller and the auxiliary roller.

Before deposition of metal film, the base film electrified with irradiation of the charged particles is made to be in close contact to the cooling roller, to which a bias potential is applied by an electrostatic attractive force. On the other hand, after deposition of the metal film, a portion of the charges on the base film are dissipated with the metal film deposition. However, a potential is applied to the metal film in contact with said auxiliary roller. Thus, electro-static attraction occurs between the metal film and the cooling roller. Accordingly, even after the deposition of metal, an attraction force is maintained between the base film and the cooling roller.

Thus, in this invention, a highly close contact force can be obtained between the base film and cooling roller both before and after the deposition of metal, and so the cooling efficiency of the film can be maintained. Thermal deformation of the base film can be prevented upon the deposition of metal and the running speed of film can be raised-and productivity can be improved.

On the other hand, when a bias potential becomes higher than a predetermined value between the cooling roller and the auxiliary roller or the metal film on the base film, there occurs the fear that evaporation metal splashes could cause a short-circuit and thermal damage and therefore the quality would be deteriorated. Preferably, the surface potential of the deposited metal film is measured and a step to control the applied voltage is provided to place it within a predetermined range. Thus, the damage due to splash of depositing metal can be avoided and stabilization of quality can be obtained. This predetermined range is within a range between a lower voltage limit suitable to obtain a close contact force between the base film and the cooling roller and an upper voltage limit which will avoid the damage due to splash occurring in the depositing method. It can be selected in accordance with the material of the base film, thickness of the base film and the film-running speed.

[Effect of the Invention]

According to this invention, a high contact force can be obtained between the insulating material base film and the cooling roller, both before and after the deposition of metal film. Thus, the thermal deformation of the insulating material film can be prevented. The film-running speed and the productivity can also be improved.

### BRIEF DESCRIPTION OF THE DRAWINGS

FIG. 1 is a schematic view of a vacuum evaporation deposition apparatus of the winding type 10 according to one embodiment of this invention;

FIG. 2 shows a film-forming surface of the insulating material base film. FIG. 2A shows the situation of formed oil pattern 25 and FIG. 2 B shows the situation after the deposition of the metal film 26;

FIG. 3 is a cross-sectional schematic view for explaining an electron beam radiating step applied to the insulating material base film 12;

FIG. 4 is a cross-sectional schematic view for explaining the attracting force between the insulating material base film 12 and the can roller 14 after the deposition of metal film;

FIG. 5 is a schematic view of a prior art vacuum evaporation deposition apparatus of the winding type.

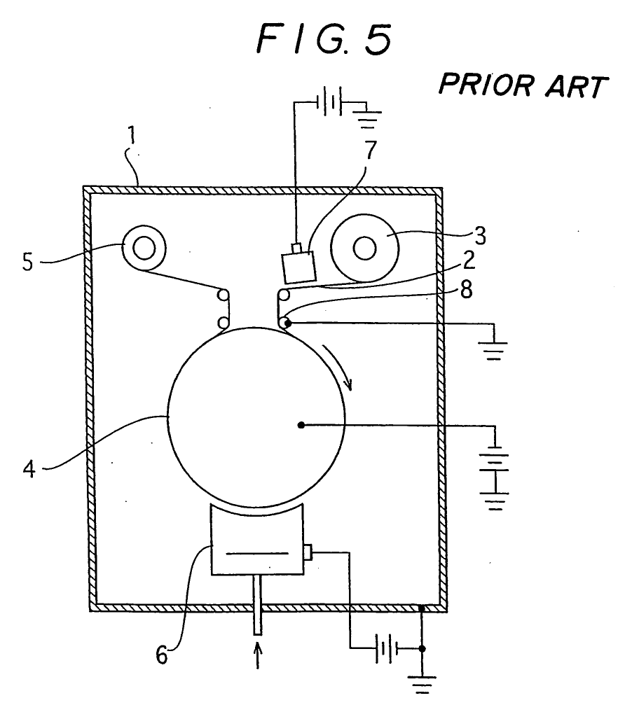

### DESIGNATIONS FOR FIGURE REFERENCE NUMERAL

10 vacuum evaporation deposition apparatus of the winding type

11 vacuum chamber

12 insulating material base film

13 unwinding roller

14 can roller (cooling roller)

15 take-up roller

16 evaporating source

18 auxiliary roller

20 pattern forming unit (mask-forming means)

21 electron beam irradiator (charged-particle irradiating means)

22 DC bias electric source (voltage applying means)

23 electricity removal means for removing electricity

25 oil pattern

26 metal film

27 sensor (detecting means)

28 controller (controlling means)

### Best Embodiment of Invention

Next, an embodiment of this invention will be described with reference to the drawings.

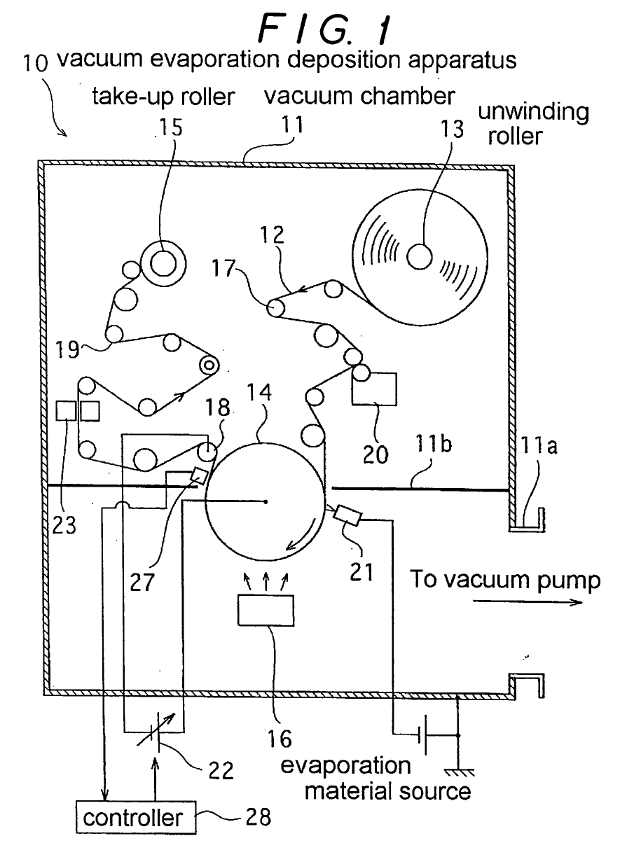

FIG. 1 is a schematic view of a vacuum evaporation deposition apparatus of the winding type according to an embodiment of this invention. The vacuum evaporation deposition apparatus 10 of the winding type according to this embodiment is provided with a vacuum chamber 11, an unwinding roller 13 for an insulating material base film 12, a cooling can roller 14, a take-up roller 15 and an evaporation deposition source 16 of material to be deposited.

The vacuum chamber 11 is connected through a conduit portion 11a to a vacuum exhaust system including a vacuum pump (not shown). The interior of the vacuum chamber 11 is exhausted to a predetermined pressure and it is partitioned into two chambers by a partition wall 11b. The unwinding roller 13 and take-up roller 15 are arranged in the one of the chambers and the evaporation source 16 is arranged in another of the chambers.

The insulating material base film 12 is a long insulating plastic film cut into a predetermined width. OPP (orienting polyplopylen) film is used in this embodiment. PET (polyethlene terephthalate) film, PPS (polyphenylene sulfide) film and a paper sheet can also be used.

The insulating material base film 12 is dispensed from the unwinding roller 13 and wound up on the take-up roller 13 after passing through plural guide rollers 17, a can roller 14, and an auxiliary roller 18 and plural guide rollers 19. The unwinding roller 13 and the take-up roller 15 correspond to the unwinding means and a take-up means of this invention. Although not shown, rotary drives are provided to drive the unwinding roller 13 and the take-up roller 15, respectively.

The can roller 14 is cylindrical in shape and it is made of metal such as stainless. A cooling mechanism, such as a circulating system of cooling water, a rotational drive mechanism for driving can roller 14 and etc, are included in the can roller 14. The insulating material base film 12 is wound about the can roller 14, and in a predetermined angle range evaporating material from the evaporating source 16 is deposited on the outside surface of the material film 12, and at the same time, the material film 12 is cooled by the can roller 14.

The evaporating source 16 contains material to be deposited. It is heated by a resistance heater, inductive heater, electron beam or a prior art heating method. A depositing material is heated in the evaporation deposition source 16, which is arranged under the can roller 14. The evaporation material from the source 16 is deposited onto the insulating material base film 12 wrapped over the can roller 14.

Metal elements such as Al, Co, Cu, Ni, and, Ti and further Al—Zn, Cu—Zn and Fe—Co alloys made of two or more kinds of metal or metal alloy may be used. Plural evaporation sources may be provided instead of one evaporation source.

The vacuum evaporation deposition apparatus 10 of the winding type according to this embodiment is provided further with a pattern forming unit 20, an electron beam irradiator 21, a DC bias source 22 and an electricity removing unit 23.

The pattern forming unit 20 forms a region for the deposition of metal film on the insulating material base film 12. It corresponds to the “mask forming means” of this invention arranged between the unwinding roller 13 and the can roller 14.

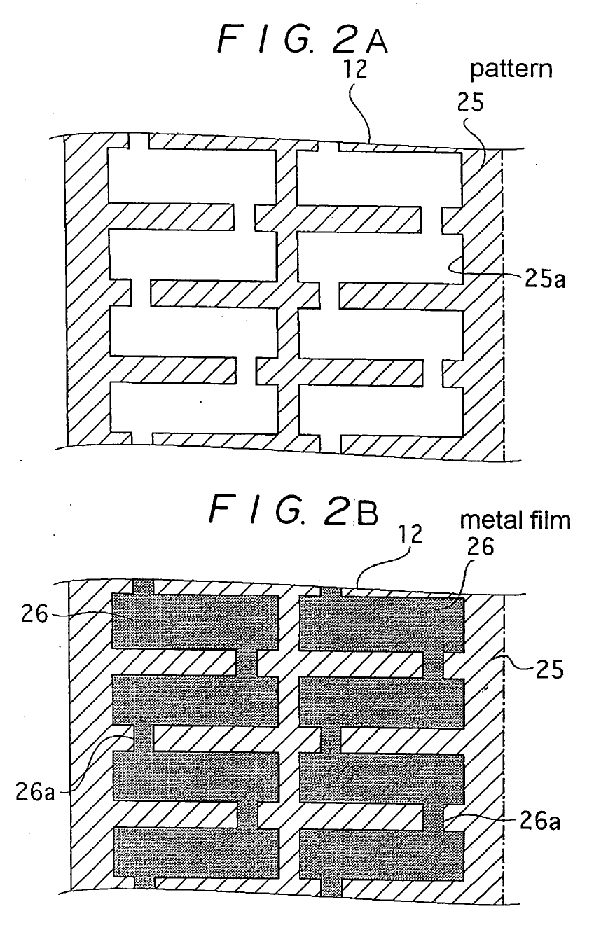

FIG. 2 shows the film-forming surface of the insulating material base film 12. The pattern forming unit 20 forms an oil pattern 25 as shown by hatching in FIG. 2A. Plural rows of oil are formed as coated on the insulating material base film 12 along the running direction or lengthwise direction. Rectangular metal patterns 25 are formed by the deposition of the material from the evaporation deposition source 16 in opening portions 25a. They are connected through connecting portions 26a at a predetermined pitch. Thus, the plural rows of metal film 26 are formed on the insulating material base film 12 as shown in FIG. 2B. Of course, the pattern of the deposited metal film is not limited to the shape shown in FIG. 2.

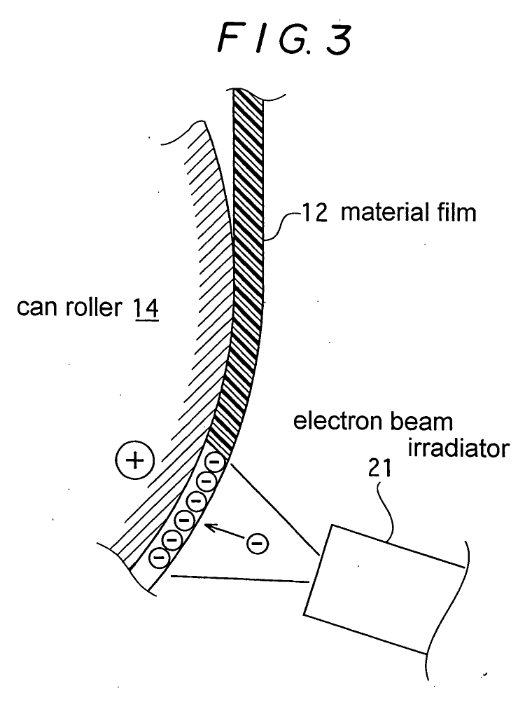

The electron beam irradiator 21 corresponds to the “charged-particles radiating means” of this invention. Electron beams, as charged particles, are irradiated onto the insulating material base film 12, and therefore it is negatively charged. FIG. 3 is a cross-sectional schematic view for explaining the radiating step of the electron beam onto the insulating material base film 12. In this embodiment, the electron beam irradiator 21 is arranged facing to the peripheral surface of the can roller 14. The electron beams are irradiated onto the surface of the insulating material base film 12. Since the electron beams are irradiated onto the film 12 which is in contact with the can roller 14, the film 12 is being cooled and receives electron beams.

In this embodiment, the electron beam irradiator 21 scans a radiating electron beam on the insulating material base film 12 in the width direction of the film 12. Thus, the film 12 is prevented from damage due to local irradiation of the electron beam onto the insulating material base film 12. Thus, the film 12 can be charged uniformly and effectively.

A predetermined DC voltage is applied between the can roller 14 and the auxiliary roller 18 by the DC bias power source 22, which corresponds to the “voltage applying means” of this invention. In the embodiment, the can roller 14 is connected to a positive electrode of the DC power source 22 and the auxiliary roller 18 is connected to a negative electrode of the DC power source 22. Thus, the insulating material base film 12 is negatively charged by the radiation of the electron beam and is electrostaticly attracted to the surface of the can roller 14 as shown in FIG. 3. Thus, the base film 12 is contacted closely with the can roller 14.

The auxiliary roller 18 is made of metal and the peripheral surface of the auxiliary roller 18 is in rolling contact with the deposition surface of the insulating material film 12.

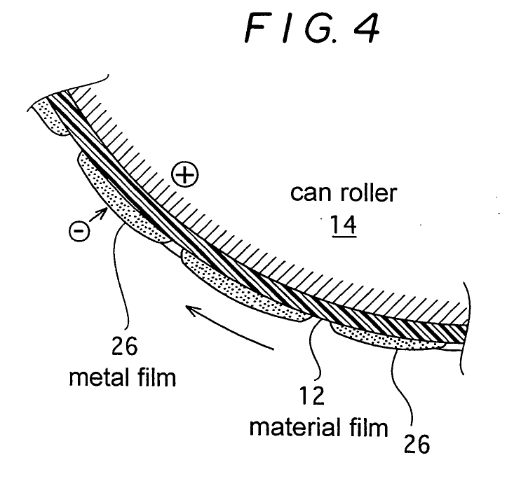

FIG. 4 is a cross-sectional schematic view for explaining the attraction between the base film 12 after deposition and the can roller 14. A pattern such as metal film 26 is formed on the base film 12 by the deposition. The metal film 26 is continuous in the longitudinal direction as shown in FIG. 2B. The auxiliary roller 18 is connected to the negative electrode of the DC voltage source 22. It guides the base film 12 on the metal film side. A negative potential is applied to the metal film in contact with the peripheral surface of the auxiliary roller 18 on the deposited surface of the metal film 26 as shown in FIG. 2B. As a result, polarization occurs in the base film 12 interposed between the metal film 26 and the can roller 14. Accordingly an electro-static attractive force occurs between the insulating material base film 12 and the can roller 14 and therefore a close contact force is obtained between the can roller 14 and the insulating material base film 12.

Particularly in this embodiment, the DC bias power source 22 is variable. The potential applied onto the metal film 26 of the insulating material base film 12 is monitored to stabilize the voltage applied to the metal film 26. Thus, lowering of the contact force of the base film 12 to the can roller 14 due to variation of the applied voltage to the metal film 26, and a short-circuit between the metal film 26 and the can roller 14, which can cause splash and damage, are avoided.

In this embodiment, the vacuum evaporation deposition apparatus 10 of the winding type is provided with a sensor 27 for detecting the surface potential of the metal film 26 on the base film 12 at the up stream side of the auxiliary roller 18 with respect to the film running direction and the controller 28. It receives the output of the detecting sensor 27 and controls the DC bias voltage source 22 so that the potential of the metal film 26 is placed within a predetermined range.

The predetermined range is between the lowest permissible voltage, which is sufficiently high as to obtain the suitable close contact force of the insulating material base film 12 to the can roller 14, and the highest permissible voltage, which is sufficiently low so as not to cause splash damage to the depositing metal. It can be suitably selected in accordance with the kind of insulating material base film 12, the thickness thereof and the film running speed, etc.

A surface potential meter of the type for measuring film surface potential is used as the sensor 27. An electrode in the measuring probe is vibrated and displacement current in accordance with the film surface potential is induced in the probe electrode. This invention is not limited to the construction used for controlling the applied voltage in accordance with a film surface potential. For example, the applied voltage may be so controlled by measuring the temperature of the base film 12.

The electricity-removing unit 23 corresponds to the electricity-removing means of this invention. It is arranged between the auxiliary roller 18 and the take-up roller 15. It has the function to remove electricity due to electron beam irradiation from the electron beam irradiator 21. In one example of the electricity-removing means, the running insulating material base film 12 is plasma-bombarded to remove electricity on film 12.

Next, the evaporation deposition method of the winding type will be described together with the operations of the evaporation deposition apparatus of the winding type 10 according to the embodiment of this invention.

The insulating material base film 12 is continuously dispensed from the unwinding roller 13. It passes through the oil-pattern forming process provided by the oil-pattern forming unit 25, the electron beam radiating process, the evaporation deposition process and the electricity-removing process and is continuously received by the take-up roller 15.

In the mask forming process, the oil pattern 25 is coated on the base film 12, for example, in the shape as shown in FIG. 2A by the pattern-forming unit 20. Instead, such a mask forming method can be employed whereby a transcription roller rolls on the base film 12 to transcribe a necessary pattern thereon.

The insulating material base film 12 with the oil pattern formed thereon is wrapped over the can roller 14. Near the position of the contact start with the can roller 14, the film 12 is irradiated with the electron beam from the electron beam irradiator 21, and it is therefore negatively charged. Since the base film 12 is irradiated with the electron beam at a position of contact with can roller 14, the material film 12 can be effectively cooled by the can roller 14. Further, since the electron beam is irradiated by scanning on the base film 12 in the width direction, the thermal deformation of the film 12 can be avoided, and further it can be uniformly and effectively charged.

The insulating material base film 12 is negatively charged by irradiation of the electron beam and is electro-statically attracted and contacted closely with the can roller 14 biased positively by the DC bias voltage source 22, as shown in FIG. 3. Material to be deposited, evaporated from the evaporation material source 16, is applied to the surface of the base film 12. Thus, the metal film 26 as stripes as shown in FIG. 2B is formed on the base film 12. Plural rows of the stripes are connected through the connecting portions 26, extending in the lengthwise direction of the film 12.

The negative potential of the DC bias voltage source 22 is applied through the auxiliary roller 18 to the metal film 26 formed on the base film 12. After the deposition of the metal film 26, the one surface of the base film 12 wrapped over the can roller 14 the same side of the metal film 26 is positively polarized, and the other surface of the base film 12 on the same side of the can roller 14 is negatively polarized. Thus, an electrostatic attractive force occurs between the base film 12 and the can roller 14. As a result, the base film 12 is closely contacted with the can roller 14.

As above described, in this embodiment, the insulating material base film 12 in close contact with the can roller 14 is charged with the irradiation of the electron beam before the deposition of the metal film 26. After the deposition of the metal film 26, the base film 12 is closely contacted with the can roller 14 with the bias voltage applied between the metal film 26 and the can roller 14. Although a portion of the charges (electrons) on the base film 12 are charged before the deposition of the metal film 26 and dissipated into the metal film during the deposition of the metal on to the base film 12, all or a portion of the dissipated charges are compensated with the application (supply of electrons) of the negative potential to the metal film 26 from the auxiliary roller 18.

Accordingly, according to the embodiment of this invention, the decrease of the contact force between the base film 12 and the can roller 14 is suppressed also after the evaporating deposition step, and so stable cooling operation of the base film 12 can be secured both before the evaporating deposition and after evaporating deposition. Thus, the thermal deformation of the film 12 can be avoided during the evaporation deposition of the metal film. The running speed of the film 12 and the metal film forming speed can be raised. Thus, the productivity can be improved. This embodiment is particularly useful for an insulating material base film 12 made of material which is hard to be charged, with the metal film deposited, such as OPP film. When the metal film 26 is pattern formed on the film 12 as in this embodiment, the temperature is raised locally, and the amount of the charges sometimes varies. The discharged metal film-forming portion is compensated with the bias voltage and so the contact force between the insulating material film and the can roller can be strengthened. That is advantages, because the insulating material base film 12 is uniformly cooled.

Further in this embodiment, since the voltage applied between the can roller 14 and the auxiliary roller 18 is controlled on the basis of the surface potential of the metal film 26 on the base film 12, the close contact between the base film 12 and the can roller 14 can be stably maintained and thermal damage such as splash can be avoided.

The metal film 26 is deposited on the insulating material film 12 in the above described manner. It is subject to electricity removal by the electricity removal unit 23 and is then taken up onto the winding roll 15. Thus, the stable winding operation of the insulating material film 12 can be secured and the insulating material film can be prevented from shrinking or wrinkling due to the electricity.

Next, an example of this invention will be described.

The maximum driving speed permissible was measured at which the metal film can be formed on the insulating material film 12 without thermal deformation such as shrink or wrinkle in the case of only the bias voltage being applied, in the case of only the electron beam radiation being applied, and in the case of applying the bias voltage plus electron beam radiation (this invention), respectively.

Insulating material film 12: OPP film 600 mm width, 4 m thickness. Metal AL film: film thickness of sheet resistance 2 ./..

Electron beam irradiator: Electron beam gun of the scanning type 4 KV×100.200 mA, scanning frequency 1000 Hz. And DC bias voltage source 22: 100.120V.

The results of the experiment are as follows:

The case of only bias voltage: 300 m/min.

The case of only electron beam radiation: 250 m/min.

The case of the bias voltage plus electron beam radiation: 500 m/min.

Thus, it has been proved according to this invention that the close contact of the insulating material film 12 with the can roller 14, can be securely obtained and the driving speed can be raised with the additional effect of the bias voltage application and the electron beam radiation.

While the preferred embodiments of the Invention have been described, without being limited to this, variations thereto will occur to those skilled in the art within the scope of the present inventive concepts that are delineated by the following claims.

For example, in the above embodiment, the metal film 26 is deposited on the insulating material film 12 in the shape of stripes connected through the connecting portions 26a as shown in FIG. 2B. The pattern is not limited to the type shown. For example, linear patterns along the lengthwise direction of the insulating material film can be employed within the scope of this invention or a metal film may be formed as single layer with a uniform patternless shape on the insulating material film 12.

Further, in the above embodiment, the electron beams are irradiated on the insulating material film 12 to negatively charge the film. Instead of the electron beam, ions may be irradiated on the insulating material film 12 to positively charge the film. In this case, polarities applied between the can roller 14 and the auxiliary roller 18 are reversed from the above embodiment. Thus, the can roller 14 is connected to the negative electrode and the auxiliary roller 18 is connected to the positive electrode.

1. A vacuum evaporation deposition method of the winding type in which, under an atmosphere of reduced pressure, an insulating material base film is continuously fed out, cooled in close contact with a cooling roller and metal is evaporated onto said insulating material base film to deposit a metal film thereon, the method characterized in that before the deposition of the metal film, said insulating material base film is closely contacted with said cooling roller by charging said insulating material base film, and after the deposition of the metal film, said insulating material base film is closely contacted with said cooling roller by applying a voltage between said metal film and said cooling roller.

2. A vacuum evaporation deposition method of the winding type according to claim 1, in which in the step of charging said insulating material base film is performed with charged particles irradiated onto the running insulating material base film while being scanned in the width direction of said insulating material base film.

3. A vacuum evaporation deposition method of the winding type according to claim 2, in which said charged particles are irradiated at a time when said insulating material base film is contacted with said cooling roller.

4. A vacuum evaporation deposition method of the winding type according to claim 1, in which in the step of applying the voltage between the metal film and said cooling roller, a DC voltage is applied between an auxiliary roller for guiding said insulating material base film with said metal film deposited thereon and said cooling roller.

5. A vacuum evaporation deposition method of the winding type according to claim 4, in which the step of applying the voltage between the metal film and said cooling roller includes a step of measuring a surface potential of said metal film and another step of so controlling the applying voltage as to place said surface potential within a predetermined range.

6. A vacuum evaporation deposition method of the winding type according to claim 1, in which a mask pattern for defining a deposition region of the metal film is formed on the surface of the insulating material base film before the step of charging the insulating material base film.

7. A vacuum evaporation deposition method of the winding type according to claim 1, in which electricity on said insulating material base film is removed after the deposition of the metal film.

8. A vacuum evaporation deposition apparatus of the winding type in which there are provided in a vacuum chamber, an unwinding roller for continuously feeding an insulating material base film, a winding roller for taking up said insulating material base film, a cooling roller for cooling said insulating material base film when in contact, said rollers arranged between said unwinding roller and said winding roller, and an evaporation source for depositing a metal film on said insulating material base film arranged facing to said cooling roller, characterized in that said apparatus includes, charged-particles irradiating means for irradiating charged particles onto said insulating material base film, said irradiating means arranged between said unwinding roller and said evaporation source, an auxiliary roller for guiding said insulating material base film in contact with the deposited metal film, said auxiliary roller arranged between said winding roller and said cooling roller, and voltage-applying means for applying a DC voltage between said auxiliary roller and said cooling roller.

9. A vacuum evaporation deposition apparatus of the winding type according to claim 8, in which there is provided detecting means for detecting a surface potential of said metal film deposited on said insulating material base film, said detecting means arranged between said cooling roller and said auxiliary roller, and controlling means for controlling the applying voltage of said voltage supplying means on the basis of the detected output of said detecting means.

10. A vacuum evaporation deposition apparatus of the winding type according to claim 8, in which said charged-particles irradiating means is arranged facing to the peripheral surface of said cooling roller.

11. A vacuum evaporation deposition apparatus of the winding type according to claim 8, in which mask-pattern forming means is arranged between said unwinding roller and said charged-particles irradiating means for defining a mask pattern of deposition regions of said metal film on said insulating material base film.

12. A vacuum evaporation deposition apparatus of the winding type according to claim 8, in which electricity removal means is arranged between said auxiliary roller and said winding roller for removing electricity eon said insulating material base film.
